(19) United States
(12) Patent Application Publication
(10) Pub. No.: US 2024/0399527 A1
(43) Pub. Date: Dec. 5, 2024

(54) INFORMATION PROCESSING APPARATUS, INFERENCE APPARATUS, MACHINE-LEARNING APPARATUS, INFORMATION PROCESSING METHOD, INFERENCE METHOD, AND MACHINE-LEARNING METHOD

(71) Applicant: EBARA CORPORATION, Tokyo (JP)

(72) Inventors: Ryo NAKAGOMI, Tokyo (JP); Takayoshi MEGURO, Tokyo (JP)

(21) Appl. No.: 18/697,703

(22) PCT Filed: Jul. 13, 2022
(86) PCT No.: PCT/JP2022/027507

§ 371 Date: Apr. 1, 2024

(30) Foreign Application Priority Data
Oct. 5, 2021 (JP) 2021-164342

(51) Int. Cl. B24B 37/005

(52) U.S. Cl. CPC B24B 37/005

(57) ABSTRACT

The present invention relates to an information processing apparatus, an inference apparatus, a machine-learning apparatus, an information processing method, an inference method, and a machine-learning method. The information processing apparatus (5) includes an information acquisition section (500) configured to acquire alarm generation information including at least alarm-type information and substrate-location information, the alarm-type information indicating a type of alarm that is generated in a substrate processing device (2) including modules and is configured to perform polishing process on substrates, the substrate-location information indicating a location state of the substrates in the modules when the alarm is generated; and a support processing section (501) configured to generate support information corresponding to the alarm by inputting the alarm generation information acquired by the information acquisition section (500) in response to the generation of the alarm to a learning model that has learned by machine learning a correlation between the alarm generation information and the support information for dealing with generation of the alarm.

### TECHNICAL FIELD

The present invention relates to an information processing apparatus, an inference apparatus, a machine-learning apparatus, an information processing method, an inference method, and a machine-learning method.

### BACKGROUND ART

A substrate processing apparatus that performs chemical mechanical polishing (CMP) is known as a type of substrate processing apparatus that performs various processes on a substrate, such as semiconductor wafer. When performing polishing of a substrate, the substrate processing apparatus monitors whether various alarm-generating conditions are met. If any of the alarm-generating conditions is met, the substrate processing apparatus generates an alarm, and displays content of the alarm (for example, see patent document 1).

### CITATION LIST

### Patent Literature

Patent document 1: Japanese laid-open patent publication No. 2007-301690

### SUMMARY OF INVENTION

### Technical Problem

When an alarm is generated in the substrate processing apparatus, a user of the substrate processing apparatus is required to analyze the cause of the alarm and is required to conduct a recovery work according to the type of alarm. In this case, since the substrate processing apparatus is composed of modules, the user should check parts of the substrate processing apparatus and parameters of the apparatus which can vary depending on a location of a substrate in each module at the time the alarm is generated. As a result, the use is required to conduct the recovery work that can vary in each case. Therefore, responding quickly and appropriately to various alarm is highly dependent on the user's individual experience and knowledge, and if the recovery work is not appropriate, more serious alarm may occur and productivity may be lowered.

In view of the above-mentioned drawbacks, it is an object of the present invention to provide an information processing apparatus, an inference apparatus, a machine-learning apparatus, an information processing method, an inference method, and a machine-learning method that enable quick and appropriate response to an alarm without depending on a user's experience or knowledge.

### Solution to Problem

In order to achieve the above object, an information processing apparatus according to an embodiment of the present invention comprises: an information acquisition section configured to acquire alarm generation information including at least alarm-type information and substrate-location information, the alarm-type information indicating a type of alarm that is generated in a substrate processing device including modules and is configured to perform polishing process on substrates, the substrate-location information indicating a location state of the substrates in the modules when the alarm is generated; and a support processing section configured to generate support information corresponding to the alarm by inputting the alarm generation information acquired by the information acquisition section in response to the generation of the alarm to a learning model that has learned by machine learning a correlation between the alarm generation information and the support information for dealing with generation of the alarm.

### Advantageous Effects of Invention

According to the information processing apparatus according to the embodiment of the present invention, the alarm generation information is input to the learning model in response to generation of an alarm, so that the support information corresponding to the alarm is generated. As a result, a user can conduct a recovery work in response to the alarm quickly and appropriately without relying on experience and knowledge of the user.

Objects, configurations, and effects other than those described above will be made clear in detailed descriptions of the invention described below.

### BRIEF DESCRIPTION OF DRAWINGS

FIG. 1 is an overall configuration diagram showing an example of a substrate processing system 1;

FIG. 2 is a plan view showing an example of a substrate processing device 2:

FIG. 3 is a perspective view showing an example of first to fourth polishing sections 220A to 220D:

FIG. 4 is a block diagram showing an example of the substrate processing device 2:

FIG. 5 is a screen configuration diagram showing an example of a substrate-location-state display screen 12:

FIG. 6 is a screen configuration diagram showing an example of a sensor monitor screen 13:

FIG. 7 is a screen configuration diagram showing an example of a recovery-operation guidance screen 14:

FIG. 8 is a screen configuration diagram showing an example of a changing-operation guidance screen 15;

FIG. 9 is a hardware configuration diagram showing an example of a computer 900:

FIG. 10 is a data configuration diagram showing an example of history information 30 managed by a database device 3:

FIG. 11 is a block diagram showing an example of the machine-learning device 4:

FIG. 12 is a data configuration diagram showing an example of learning data 11:

FIG. 13 is a schematic diagram showing an example of a neural network model that constitutes a learning model 10 used in the machine-learning device 4:

FIG. 14 is a flowchart showing an example of a machine-learning method performed by the machine-learning device 4:

FIG. 15 is a block diagram showing an example of an information processing device 5; and

FIG. 16 is a flowchart showing an example of an information processing method performed by the information processing device 5.

### DESCRIPTION OF EMBODIMENTS

Embodiments for practicing the present invention will be described below with reference to the drawings. In the following descriptions, scope necessary for the descriptions to achieve the object of the present invention will be schematically shown, scope necessary for the descriptions of relevant parts of the present invention will be mainly described, and parts omitted from the descriptions will be based on known technology.

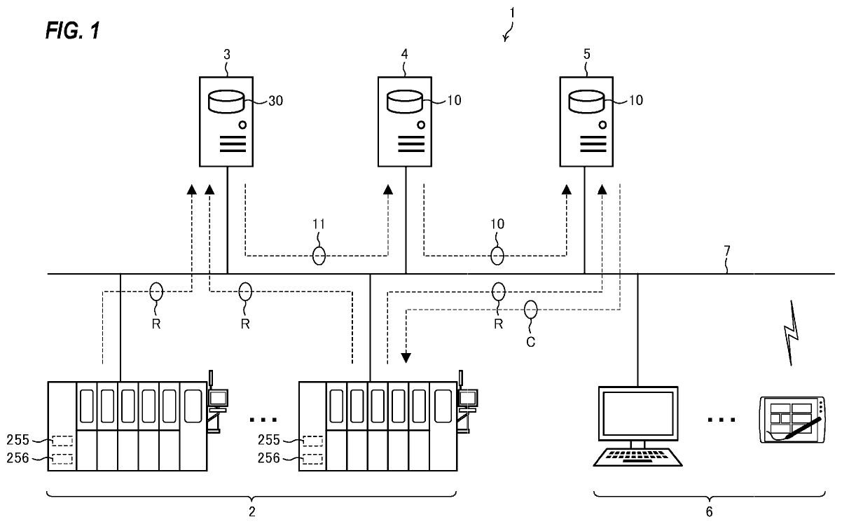

FIG. 1 is an overall configuration diagram showing an example of a substrate processing system 1. As shown in FIG. 1, the substrate processing system 1 according to the present embodiment functions as a system configured to manage a substrate processing in which a chemical mechanical polishing (hereinafter referred to as “polishing process”) is performed on a substrate (hereinafter referred to as “wafer”) W, such as a semiconductor wafer.

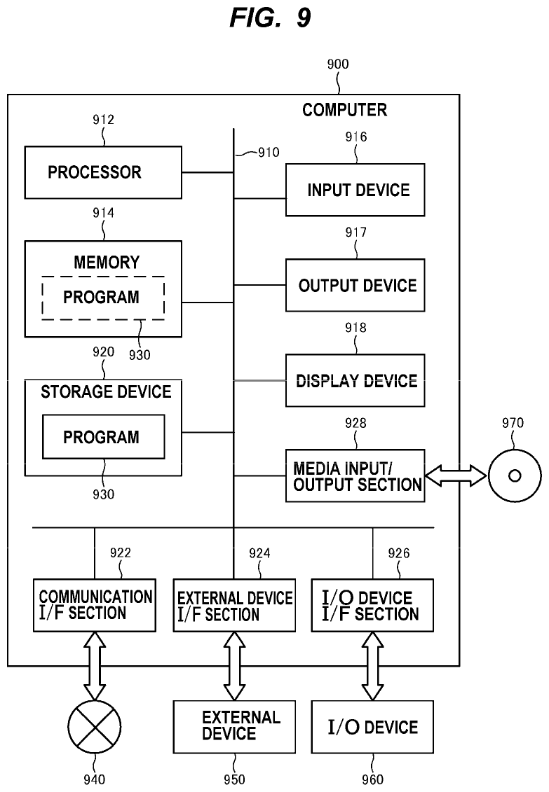

The substrate processing system 1 includes, as its main components, substrate processing devices 2, a database device 3, a machine-learning device 4, an information processing device 5, and a user terminal device 6. Each of the devices 2 to 6 is configured with, for example, a general-purpose or dedicated computer (see FIG. 9 described later). The devices 2 to 6 are coupled to a wired or wireless network 7 so as to be able to mutually transmit and receive various data (some data are shown in FIG. 1 with dotted arrows). It is noted that that the number of devices 2 to 6 and the connection configuration of the network 7 are not limited to the example shown in FIG. 1 and may be changed as appropriate.

Each substrate processing device 2 is an apparatus configured to perform the polishing process on a wafer W to planarize a surface of the wafer W. The substrate processing device 2 is composed of modules and is configured to perform a series of polishing operations on one or more wafers W, such as loading, polishing, cleaning, drying, film-thickness measuring, and unloading. During the operations, the substrate processing device 2 refers to device setting information 255 including device parameters that have been set for the modules and substrate recipe information 256 that determines polishing conditions in the polishing process. If the state of each module meets a predetermined alarm-generating condition, the substrate processing device 2 generates an alarm.

The substrate processing device 2 is configured to transmit various reports R regarding the alarm generated in the substrate processing device 2, an location state of wafers W in the modules, an operating state of each module, manipulations by a user (an operator, a production manager, a maintenance manager, etc.) for the substrate processing device 2, and events detected in the substrate processing device 2 to other devices. Furthermore, when the substrate processing device 2 receives various commands C from other devices, the substrate processing device 2 operates according to the commands C, for example.

Alarms are classified into multiple types according to different alarm-generating conditions. The types of alarms are identified by codes, numbers, etc. The alarm-generating conditions are provided for monitoring malfunction of each module, timeout, state mismatch, etc. Alarm levels are set as mild, moderate, and severe. The alarm is notified to the user via, for example, a display screen of the substrate processing device 2, lighting of a signal tower, a buzzer sound, or a display screen of the user terminal device 6.

When the alarm is generated in the substrate processing device 2, the user of the substrate processing device 2 is required to analyze the cause of the alarm or restore an alarm state back to a normal state depending on the type of alarm. At this time, the modules and device parameters that the user should check differ depending on the location state of the wafers W existing inside the substrate processing device 2 when the alarm is generated, and as a result, a necessary recovery work will also differ. Therefore, in order to assist in dealing with the alarm generation, the substrate processing system 1 employs machine learning that uses learning data 11 including operations that have been performed in the past by a user (for example, a user with experience and knowledge for dealing with an alarm) for analysis and recovery in response to the generation of the alarm.

The database device 3 is an apparatus that manages history information 30 when the polishing process is performed in the substrate processing device 2. The database device 3 receives the various reports R from the substrate processing device 2 at any time and registers the reports R for each substrate processing device 2 in the history information 30, so that contents of the report R are accumulated in the history information 30 along with date and time information. In addition to the history information 30, the database device 3 may also store the device setting information 255 and the substrate recipe information 256. In that case, the substrate processing device 2 may refer to these information.

The machine-learning device 4 operates as a main configuration for the learning phase in the machine learning. For example, the machine-learning device 4 acquires, as the learning data 11, part of the history information 30 from the database device 3, and performs the machine learning to create a learning model 10 to be used in the information processing device 5. The learning model 10 as the learned model is provided to the information processing device 5 via the network 7, a storage medium, or the like. In this embodiment, supervised learning is employed as a method of the machine learning.

The information processing device 5 operates as a main configuration for an inference phase in the machine learning. When an alarm is generated in the substrate processing device 2, the information processing device 5 uses the learning model 10, created by the machine-learning device 4, to generate support information corresponding to the alarm and transmits a command C regarding the support information to the substrate processing device 2 or the user terminal device 6. The support information may be generated as user-presentation information to be provided to the user of the substrate processing device 2, or may be generated as device-presentation information to be provided to the substrate processing device 2.

The user terminal device 6 is a terminal device used by a user. The user terminal device 6 may be a stationary device or a portable device. The user terminal device 6 receives various input manipulations via a display screen of an application program, a web browser, etc., and displays various information (for example, alarm notification, the support information, the history information 30, etc.) via the display screen.

### (Substrate Processing Device 2)

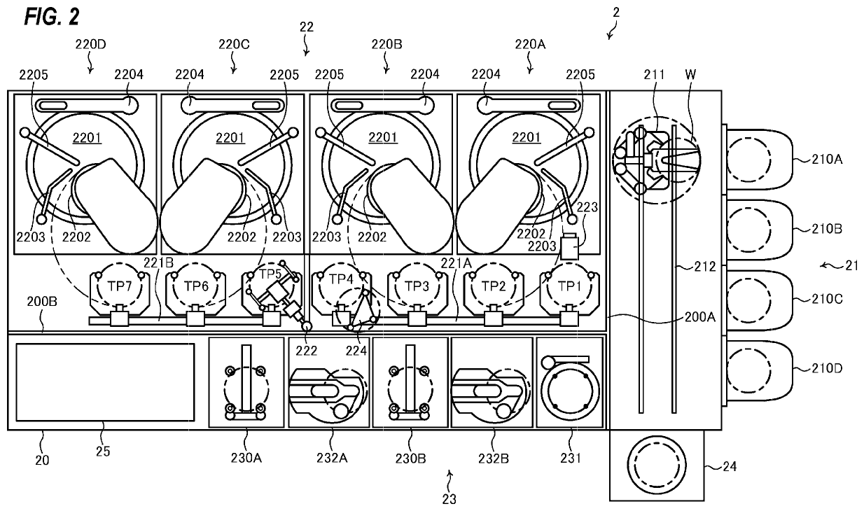

FIG. 2 is a plan view showing an example of the substrate processing device 2. The substrate processing device 2 includes a load-unload unit 21, a polishing unit 22, a cleaning unit 23, a film-thickness measuring unit 24, and a control unit 25, which are arranged inside a housing 20 that is substantially rectangular in a plan view. The load-unload unit 21 and the polishing unit 22 and cleaning unit 23 are partitioned by a first partition wall 200A. The polishing unit 22 and the cleaning unit 23 are partitioned by a second partition wall 200B.

### (Load-Unload Unit)

The load-unload unit 21 includes first to fourth front load sections 210A to 210D on which wafer cassettes (FOUPs, etc.), capable of storing a large number of wafers W along a vertical direction, are placed, a transfer robot 211 that is movable along the storage direction (vertical direction) of the wafers W in each wafer cassette, and a moving mechanism 212 for moving the transfer robot 211 along an arrangement direction of the first to fourth front load sections 210A to 210D (i.e., along a direction of a shorter side of the housing 20).

The transfer robot 211 is configured to be accessible to the wafer cassette placed on each of the first to fourth front load sections 210A to 210D, the polishing unit 22 (specifically, a lifter 223, which will be described later), the cleaning unit 23 (specifically, a drying chamber 231, which will be described later), and the film-thickness measuring unit 24. The transfer robot 211 includes upper and lower hands (not shown) for transporting the wafer W between the wafer cassette, the polishing unit 22, the cleaning unit 23, and the film-thickness measuring unit 24. The lower hand is used when transporting the wafer W before processing of the wafer W, and the upper hand is used when transporting the wafer W after processing of the wafer W. When the wafer W is transported to and from the polishing unit 22 or the cleaning unit 23, a shutter (not shown) provided on the first partition wall 200A is opened and closed. Two or more transport robots 211 may be provided.

### (Polishing Unit)

The polishing unit 22 includes first to fourth polishing sections 220A to 220D each configured to perform the polishing process (planarization) on the wafer W. The first to fourth polishing sections 220A to 220D are arranged in parallel along the longitudinal direction of the housing 20.

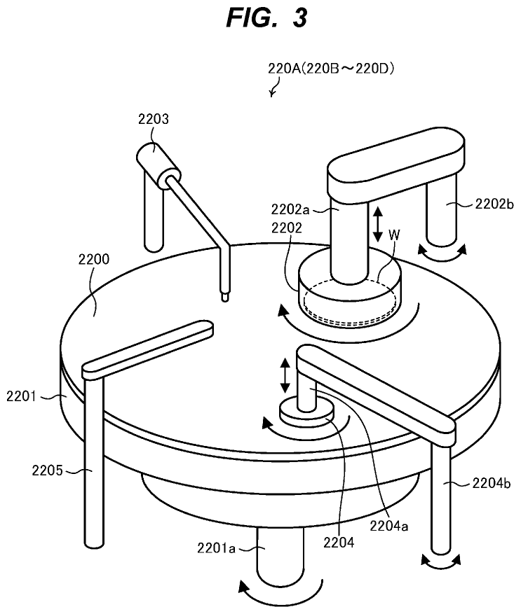

FIG. 3 is a perspective view showing an example of the first to fourth polishing sections 220A to 220D. The first to fourth polishing sections 220A to 220D have common basic configurations and functions.

Each of the first to fourth polishing units 220A to 220D includes a polishing table 2201 to which a polishing pad 2200 having a polishing surface is attached, a top ring 2202 for holding the wafer W and polishing the wafer W while pressing the wafer W against the polishing pad 2200 on the polishing table 2201, a polishing-liquid supply nozzle 2203 for supplying a polishing liquid (slurry) or a dressing liquid (for example, pure water) to the polishing pad 2200, a dresser 2204 for dressing the polishing surface of the polishing pad 2200, and an atomizer 2205 for atomizing a mixture of a liquid (for example, pure water) and a gas (for example, nitrogen gas) or atomizing a liquid (for example, pure water) and emitting the atomized fluid onto the polishing surface.

The polishing table 2201 is supported by a polishing table shaft 2201a and is configured to rotate around an axis of the polishing table 2201. The top ring 2202 is supported by a top ring shaft 2202a that is movable in the vertical direction, and is configured to rotate around an axis of the top ring 2202 and swing around a support shaft 2202b. The dresser 2204 is supported by a dresser shaft 2204a that is movable in the vertical direction, and is configured to be driven to rotate around an axis of the dresser 2204 and to rotate around a support shaft 2204b. The wafer W is held on the lower surface of the top ring 2202 by vacuum suction and is moved to a predetermined polishing position. The polishing liquid is supplied from the polishing-liquid supply nozzle 2203 onto the polishing surface of the polishing pad 2200, and the wafer W polished by being pressed against the polishing pad 2200 by the top ring 2202.

As shown in FIG. 2, the polishing unit 22 includes first and second linear transporters 221A, 221B that are movable along an arrangement direction of the first to fourth polishing sections 220A to 220D (i.e., the longitudinal direction of the housing 20), a swing transporter 222 arranged between the first and second linear transporters 221A, 221B, a lifter 223 arranged near the load-unload unit 21, and a temporary station 224 for the wafer W arranged near the cleaning unit 23.

The first linear transporter 221A is arranged adjacent to the first and second polishing sections 220A and 220B and is configured to transport the wafer W to four transfer positions (which will be referred to as first to fourth transfer positions TP1 to TP4 in the order from the load-unload-unit-21-side). The second transfer position TP2 is a position where the wafer W is delivered to the first polishing section 220A. The top ring 2202 of the first polishing section 220A is configured to be movable between the second transfer position TP2 and the polishing position by the swinging motion of the top ring 2202 of the first polishing section 220A. The third transfer position TP3 is a position where the wafer W is delivered to the second polishing section 220B. The top ring 2202 of the second polishing section 220B is configured to be movable between the third transfer position TP3 and the polishing position by the swinging motion of the top ring 2202 of the second polishing section 220B.

The second linear transporter 221B is arranged adjacent to the third and fourth polishing sections 220C and 220D and is configured to transport the wafer W to three transfer positions (which will be referred to as fifth to seventh transfer positions TP5 and TP7 in the order from the load-unload-unit-21-side). The sixth transfer position TP6 is a position where the wafer W is delivered to the third polishing section 220C. The top ring 2202 of the third polishing section 220C is configured to be movable between the sixth transfer position TP6 and the polishing position by the swinging motion of the top ring 2202 of the third polishing section 220C. The seventh transfer position TP7 is a position where the wafer W is delivered to the fourth polishing section 220D. The top ring 2202 of the fourth polishing section 220D is configured to be movable between the seventh transfer position TP7 and the polishing position by the swinging motion of the top ring 2202 of the fourth polishing section 220D.

The swing transporter 222 is disposed adjacent to the fourth and fifth transfer positions TP4 and TP5. The swing transporter 222 has a hand that is movable between the fourth and fifth transfer positions TP4 and TP5. The swing transporter 222 is configured to transport the wafer W between the first and second linear transporters 221A and 221B and place the wafer W temporarily on the temporary station 224.

The lifter 223 is disposed adjacent to the first transfer position TP1. The lifter 223 is configured to transport the wafer W between the first transfer position TP1 and the transfer robot 211 of the load-unload unit 21. When the wafer W is transported, the shutter (not shown) provided on the first partition wall 200A is opened and closed.

### (Cleaning Unit)

The cleaning unit 23 includes first and second cleaning chambers 230A and 230B for cleaning the wafer W using cleaning liquid, a drying chamber 231 for drying the wafer W, and first and second transporting chambers 232A and 232B for transporting the wafer W. These chambers of the cleaning unit 23 are partitioned and arranged along the first and second linear transporters 221A and 221B. For example, the chambers of the cleaning unit 23 are arranged in the order of the first cleaning chamber 230A, the first transporting chamber 232A, the second cleaning chamber 230B, the first transporting chamber 232B, and the drying chamber 231 (in the order of distance from the load-unload unit 21).

The first cleaning chamber 230A uses roll sponge scrub. Specifically, the first cleaning chamber 230A includes therein an upper primary cleaning module and a lower primary cleaning module arranged along the vertical direction. The second cleaning chamber 230B uses pencil sponge scrub. Specifically, the second cleaning chamber 230B includes therein an upper secondary cleaning module and a lower secondary cleaning module arranged along the vertical direction. The drying chamber 231 includes an upper drying module and a lower drying module arranged along the vertical direction for drying the wafer W using, for example, isopropyl alcohol (IPA).

The first transporting chamber 232A includes therein a first transfer robot 233A that is movable in the vertical direction. The first transfer robot 233A is configured to be able to access the temporary station 224 of the polishing unit 22, the first cleaning chamber 230A, and the second cleaning chamber 230B, and has upper and lower hands (not shown) configured to transport the wafer W between them. For example, the lower hand is used to transport the wafer W before cleaning of the wafer W, and the upper hand is used to transport the wafer W after cleaning of the wafer W. When the wafer W is transported from the temporary station 224, a shutter (not shown) provided on the second partition wall 200B is opened and closed.

The second transporting chamber 232B includes therein a second transfer robot 233B that is movable in the vertical direction. The second transfer robot 233B is configured to be able to access the second cleaning chamber 230B and the drying chamber 231, and has a hand (not shown) for transporting the wafer W between them.

### (Film-Thickness Measuring Unit)

The film-thickness measuring unit 24 includes an upper film-thickness measuring module, a middle film-thickness measuring module, and a lower film-thickness measuring module which are arranged along the vertical direction. Each film-thickness measuring module is a measuring device configured to measure a film thickness of the wafer W before or after the polishing process. Each film-thickness measuring module is, for example, an optical film-thickness measuring device, an eddy current type film-thickness measuring device, or the like. The transfer robot 211 transports the wafer W to and from each film-thickness measuring module.

### (Control Unit)

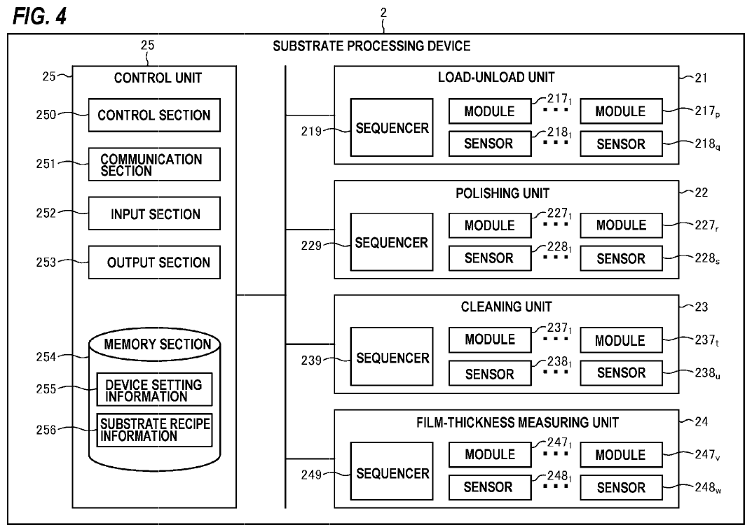

FIG. 4 is a block diagram showing an example of the substrate processing device 2. The control unit 25 is electrically coupled to each of the units 21 to 24 and functions as a control section that comprehensively controls each of the units 21 to 24.

The load-unload unit 21 includes modules 2171 to 217p (for example, the transfer robot 211, etc.) composed of various actuators, sensors 2181 to 218q arranged in the modules 2171 to 217p, respectively, for detecting data (detection values) necessary for controlling the modules 2171 to 217p, and a sequencer 219 for controlling the operations of the modules 2171 to 217p based on the detection values of the sensors 2181 to 218q.

Examples of the sensors 2181 to 218q of the load-unload unit 21 include sensors for detecting the presence or absence of the wafer cassettes on the first to fourth front loading sections 210A to 210D, a sensor for detecting the presence or absence of the wafer W on the upper hand of the transfer robot 211, and a sensor for detecting the presence or absence of the wafer W on the lower hand of the transfer robot 211.

The polishing unit 22 includes modules 2271 to 227r composed of various actuators (for example, the first to fourth polishing sections 220A to 220D, the first and second linear transporters 221A and 221B, the swing transporter 222, the lifter 223, etc.), sensors 2281 to 228s arranged in the modules 2271 to 227r, respectively, for detecting data (detection values) necessary for controlling the modules 2271 to 227r, and a sequencer 229 for controlling the operations of the modules 2271 to 227r based on the detection values of the sensors 2281 to 228s.

Examples of the sensors 2281 to 228s of the polishing unit 22 include sensors for detecting the presence or absence of the wafers W in the first to fourth polishing sections 220A to 220D, sensors for detecting the presence or absence of the wafers W in the first to seventh transfer positions TP1 to TP7, a sensor for detecting the presence or absence of the wafer W on the swing transporter 222, a sensor for detecting the presence or absence of the wafer W on the lifter 223, a sensor for detecting the presence or absence of the wafer W on the temporary station 224, a sensor for detecting a flow rate of the polishing liquid supplied to the polishing pad 2200, a sensor for detecting a rotation speed of the polishing table 2201, a sensor for detecting a rotation speed of the top ring 2202, a sensor for detecting a rotation torque of the top ring 2202, a sensor for detecting a height of the top ring 2202, and a sensor for detecting a rotation speed of the dresser 2204.

The cleaning unit 23 includes modules 2371 to 237t (for example, the first cleaning chamber 230A, the second cleaning chamber 230B, the drying chamber 231, etc.) configured with various actuators, sensors 2381 to 238u arranged in the modules 2371 to 237t, respectively, for detecting data (detection values) necessary for controlling the modules 2371 to 237t, and a sequencer 239 for controlling the operations of the modules 2371 to 237t based on the detection values of the sensors 2381 to 238u.

Examples of the sensors 2381 to 238u of the cleaning unit 23 include a sensor for detecting the presence or absence of the wafer W in the upper primary cleaning module, a sensor for detecting the presence or absence of the wafer W in the lower primary cleaning module, a sensor for detecting the presence or absence of the wafer W in the upper secondary cleaning module, a sensor for detecting the presence or absence of the wafer W in the lower secondary cleaning module, a sensor for detecting the presence or absence of the wafer W in the upper drying module, a sensor for detecting the presence or absence of the wafer W in the lower drying module, a sensor for detecting the presence or absence of the wafer W on the upper hand of the first transfer robot 233A, a sensor for detecting the presence or absence of the wafer W on the lower hand of the first transfer robot 233A, a sensor for detecting the presence or absence of the wafer W on the hand of the second transfer robot 233B, a sensor for detecting a flow rate of the cleaning liquid in the first cleaning chamber 230A, and a sensor for detecting a flow rate of the cleaning liquid in the second cleaning chamber 230B.

The film-thickness measuring unit 24 includes modules 2471 to 247v (for example, the upper film-thickness measuring module, the middle film-thickness measuring module, the lower film-thickness measuring module, etc.) configured with various actuators, sensors 2481 to 248w arranged in the modules 2471 to 247v, respectively, for detecting data (detection values) necessary for controlling the modules 2471 to 247v, and a sequencer 249 for controlling the operations of the modules 2471 to 247v based on the detection values of the sensor 2481 to 248w.

Examples of the sensors 2481 to 248w of the film-thickness measuring unit 24 include a sensor for detecting the presence or absence of the wafer W in the upper film-thickness measuring module, a sensor for detecting the presence or absence of the wafer W in the middle film-thickness measuring module, and a sensor for detecting the presence or absence of the wafer W in the lower film-thickness measuring module.

The control unit 25 includes a control section 250, a communication section 251, an input section 252, an output section 253, and a memory section 254. The control unit 25 is comprised of, for example, a general-purpose or dedicated computer (see FIG. 9, which will be described later).

The communication section 251 is coupled to the network 7 and functions as a communication interface for transmitting and receiving various data. The input section 252 receives various input operations. The output section 253 functions as a user interface by outputting various information via a display screen, lighting of signal tower, or buzzer sound.

The memory section 254 stores therein various programs (operating system (OS), application programs, web browser, etc.) and data (the device setting information 255, the substrate recipe information 256, etc.) used in the operations of the substrate processing device 2. The device setting information 255 and the substrate recipe information 256 are data that can be edited by the user via the display screen.

The control section 250 obtains detection values of the sensors 2181 to 218q, 2281 to 228s, 2381 to 238u, and 2481 to 248w (hereinafter referred to as “sensor group”) via the sequencers 219, 229, 239, and 249 (hereinafter referred to as “sequencer group”). The control section 250 operates the modules 2171 to 217p, 2271 to 227r, 2371 to 237t, and 2471 to 247v (hereinafter referred to as “module group”) in cooperation to perform the polishing process on the wafer W.

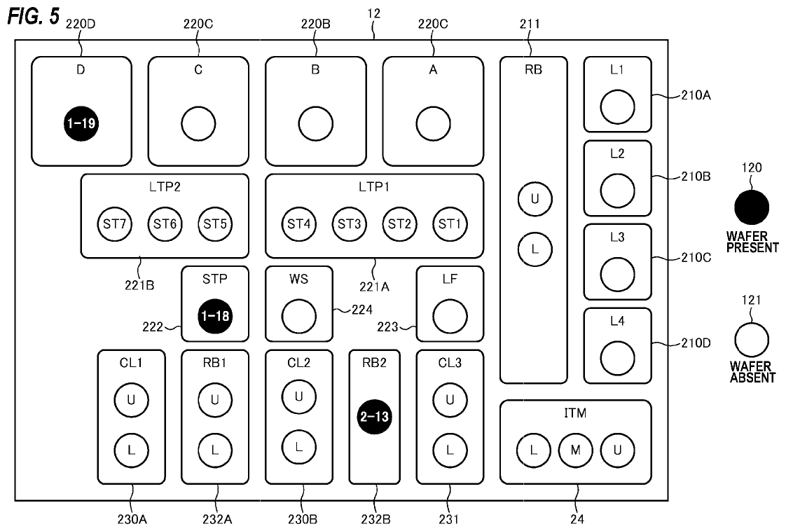

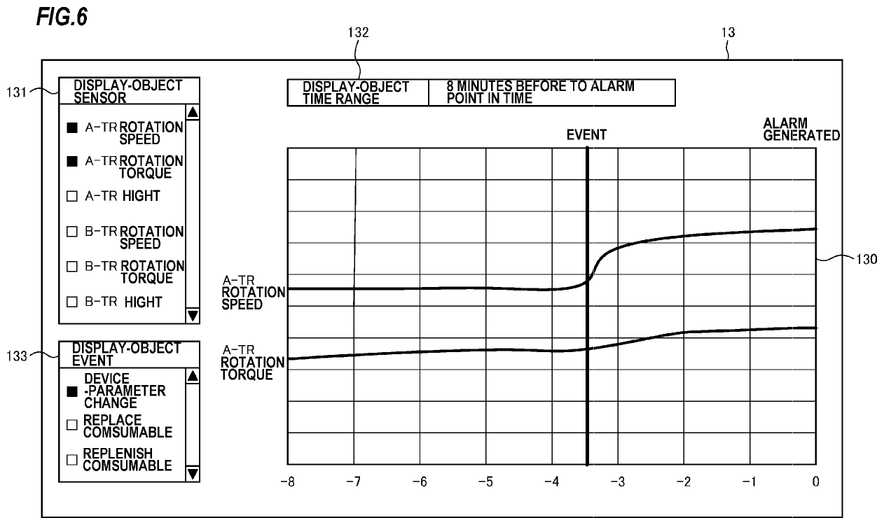

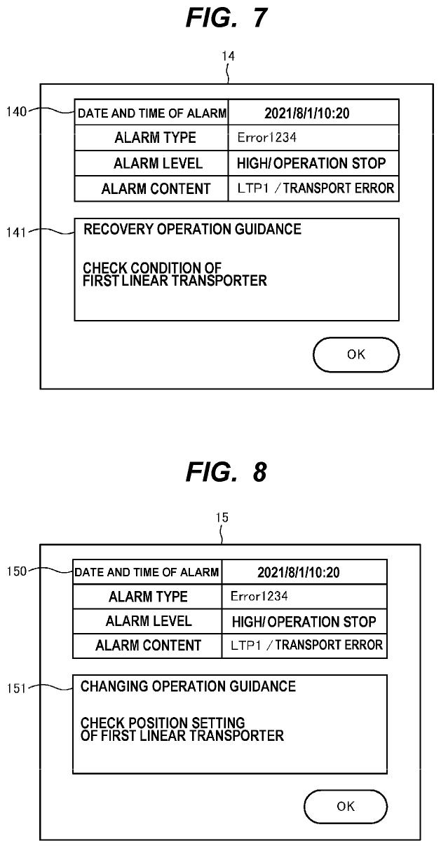

The control section 250 displays various display screens via the output section 253 and receives various input manipulations via the input section 252 to update the display screen and data. The display screen includes, for example, a device-parameter editing screen on which device parameters included in the device setting information 255 can be edited, a substrate-recipe editing screen on which polishing conditions for the wafer W included in the substrate recipe information 256 can be edited, a substrate-location-state display screen that can display the location state of the wafers W existing at respective positions of the module group (see FIG. 5 described later), a sensor monitor screen that can display a change over time in the detection value of at least one sensor among the sensor group (see FIG. 6 described later), a recovery-operation guidance screen that can display guidance of a recovery operation for at least one module among the module group (see FIG. 7 described later), a changing-operation guidance screen that can display a guidance of a changing operation for at least one device parameter among the device parameters (see FIG. 8 described later).

FIG. 5 is a screen configuration diagram showing an example of a substrate-location-state display screen 12. The substrate-location-state display screen 12 displays a wafer present mark 120 indicating that a wafer W exists, and a wafer absent mark 121 indicating that a wafer W does not exist, on a layout representing positions where wafers W can stay in the module group. The presence or absence of the wafer W is detected by the sensor group provided at respective positions. The substrate-location-state display screen 12 is updated when the wafer W is transported and the detection values of the sensor group change as the polishing process progresses. In the example of FIG. 5, three wafer present marks 120 indicate that a wafer W with cassette number 1 and slot number 18 is present on the swing transporter 222, a wafer W with cassette number 1 and slot number 19 is present in the fourth polishing section 220D, and a wafer W with cassette number 2 and slot number 13 is present in the second transporting chambers 232B.

FIG. 6 is a screen configuration diagram showing an example of the sensor monitor screen 13. The sensor monitor screen 13 includes a graph area 130 that displays a change over time in the detection value of at least one sensor which is a display object and a detection time point of at least one event which is a display object. The sensor monitor screen 13 further includes a display-object sensor identifying field 131 for identifying at least one sensor to be displayed in the graph area 130, a display-object time range specifying field 132 for specifying a time range when displaying the change over time in the graph area 130, and a display-object event identifying field 133 for identifying at least one event to be displayed in the graph area 130. In the graph area 130, for example, the detection values of the sensor that have been sampled with a predetermined period are displayed in time series. In the example of FIG. 6, the graph area 130 displays the detection values of the rotational speed of the top ring and the rotational torque of the top ring from eight minutes before to a time of alarm generated. The graph area 130 further displays a detection time of a device-parameter changing event.

FIG. 7 is a screen configuration diagram showing an example of a recovery-operation guidance screen 14. The recovery-operation guidance screen 14 includes an alarm display field 140 that displays date and time when the alarm is generated, the type of alarm, the level of the alarm, and content of the alarm. The recovery-operation guidance screen 14 further includes a recovery-operation guidance field 141 that displays a guidance of a recovery operation for at least one module.

FIG. 8 is a screen configuration diagram showing an example of a changing-operation guidance screen 15. The changing-operation guidance screen 15 includes an alarm display field 150 that displays date and time when the alarm is generated, the type of alarm, the level of the alarm, and content of the alarm. The changing-operation guidance screen 15 further includes a changing-operation guidance field 151 that displays a guidance for changing at least one device parameter.

The control section 250 transmits various reports R to, for example, the database device 3, the information processing device 5, the user terminal device 6, etc. The report R includes, for example, a report R regarding the generation of the alarm, a report R regarding the location state of the wafers W based on the detection values of the sensor group, a report R regarding the operation states of the module group, a report R regarding manipulations of the user received via the input section 252 or the user terminal device 6, a report R regarding events related to setting changes in the device setting information 255 and the substrate recipe information 256, etc.

When the control section 250 receives various commands C from the information processing device 5, the user terminal device 6, etc., the control section 250 operates according to the commands C. The commands C include, for example, a command C regarding the user-presentation information and a command C regarding the device-presentation information, both of which are related to the support information generated by the information processing device 5.

The user-presentation information includes, for example, display-object sensor information that identifies at least one sensor to be displayed on the sensor monitor screen 13. The display-object sensor information corresponds to the display-object sensor identifying field 131 on the sensor monitor screen 13. When the control section 250 receives the command C including the display-object sensor information, the control section 250 displays the sensor monitor screen 13 on which the sensor identified by the display-object sensor information is identified in the display-object sensor identifying field 131. The user-presentation information may include display-object time range information that specifies the time range when displaying the change over time on the sensor monitor screen 13, or may include display-object event information that identifies at least one event to be displayed on the sensor monitor screen 13. The display-object time range information corresponds to the display-object time range specifying field 132, and the display-object event information corresponds to the display-object event identifying field 133.

The user-presentation information includes display-object module information that identifies at least one module to be displayed on the recovery-operation guidance screen 14. The display-object module information corresponds to the recovery-operation guidance field 141 of the recovery-operation guidance screen 14. When the control section 250 receives the command C including the display-object module information, the control section 250 displays in the recovery-operation guidance field 141 the guidance of the recovery operation for the module that is identified by the display-object module information.

The user-presentation information further includes display-object device parameter information that identifies at least one device parameter to be displayed on the changing-operation guidance screen 15. The display-object device parameter information corresponds to the changing-operation guidance field 151 of the changing-operation guidance screen 15. When the control section 250 receives the command C including the display-object device parameter information, the control section 250 displays in the changing-operation guidance field 151 the guidance for changing the device parameter identified by the display-object device parameter information.

The device-presentation information includes designation-object device parameter information that identifies at least one device parameter to be identified with respect to changing-process designation data that can designate a changing process for at least one device parameter among the device parameters. When the control section 250 receives the command C including the designation-object device parameter information, the control section 250 changes the device parameter identified by the designation-object device parameter information to thereby change the device setting information 255.

### (Hardware Configuration of Each Device)

FIG. 9 is a hardware configuration diagram showing an example of a computer 900. Each of the control unit 25, the database device 3, the machine-learning device 4, the information processing device 5, and the user terminal device 6 of the substrate processing device 2 is configured by the general-purpose or dedicated computer 900.

As shown in FIG. 9, main components of the computer 900 include buses 910, a processor 912, a memory 914, an input device 916, an output device 917, a display device 918, a storage device 920, a communication I/F (interface) section 922, an external device I/F section 924, an I/O (input/output) device I/F section 926, and a media input/output section 928. The above components may be omitted as appropriate depending on an application in which the computer 900 is used.

The processor 912 includes one or more arithmetic processing unit(s) (CPU (Central Processing Unit), MPU (Micro-processing unit), DSP (digital signal processor), GPU (Graphics Processing Unit), etc.), and operates as a controller configured to control the entire computer 900. The memory 914 stores various data and programs 930, and includes, for example, a volatile memory (DRAM, SRAM, etc.) that functions as a main memory, a non-volatile memory (ROM), a flash memory, etc.

The input device 916 includes, for example, a keyboard, a mouse, a numeric keypad, an electronic pen, etc., and functions as an input section. The output device 917 includes, for example, a sound (voice) output device, a vibration device, etc., and functions as an output section. The display device 918 includes, for example, a liquid crystal display, an organic EL display, electronic paper, a projector, etc., and functions as an output section. The input device 916 and the display device 918 may be configured integrally, such as a touch panel display. The storage device 920 includes, for example, HDD (Hard Disk Drive), SSD (Solid State Drive), etc., and functions as a storage section. The storage device 920 stores various data necessary for executing the operating system and the programs 930.

The communication I/F section 922 is coupled to a network 940, such as the Internet or an intranet (which may be the same as the network 7 in FIG. 1), in a wired manner or a wireless manner, and transmits and receives data to and from another computer according to a predetermined communication standard. The communication I/F section 922 functions as a communication unit that sends and receives information. The external device I/F section 924 is coupled to an external device 950, such as camera, printer, scanner, reader/writer, etc. in a wired manner or a wireless manner, and serves as a communication section that transmits and receives data to and from the external device 950 according to a predetermined communication standard. The I/O device I/F unit 926 is coupled to I/O device 960, such as various sensors or actuators, and functions as a communication unit that transmits and receives various signals, such as detection signals from the sensors or control signals to the actuators, and data to and from the I/O device 960. The media input/output unit 928 is constituted of a drive device, such as a DVD (Digital Versatile Disc) drive or a CD (Compact Disc) drive, and writes and reads data into and from medium (non-transitory storage medium) 970, such as a DVD or a CD.

In the computer 900 having the above configurations, the processor 912 calls the program 930 stored in the storage device 920 into the memory 914 and executes the program 930, and controls each part of the computer 900 via the buses 910. The program 930 may be stored in the memory 914 instead of the storage device 920. The program 930 may be stored in the medium 970 in an installable file format or an executable file format, and may be provided to the computer 900 via the media input/output unit 928. The program 930 may be provided to the computer 900 by being downloaded via the network 940 and the communication I/F unit 922. The computer 900 performs various functions realized by the processor 912 executing the programs 930. The computer 900 may include hardware, such an FPGA (field-programmable gate array), an ASIC (application specific integrated circuit), etc. for executing the above-described various functions.

The computer 900 is, for example, a stationary computer or a portable computer, and is an electronic device in arbitrary form. The computer 900 may be a client computer, a server computer, or a cloud computer. The computer 900 may be applied to devices other than the devices 2 to 6.

### (History Information 30)

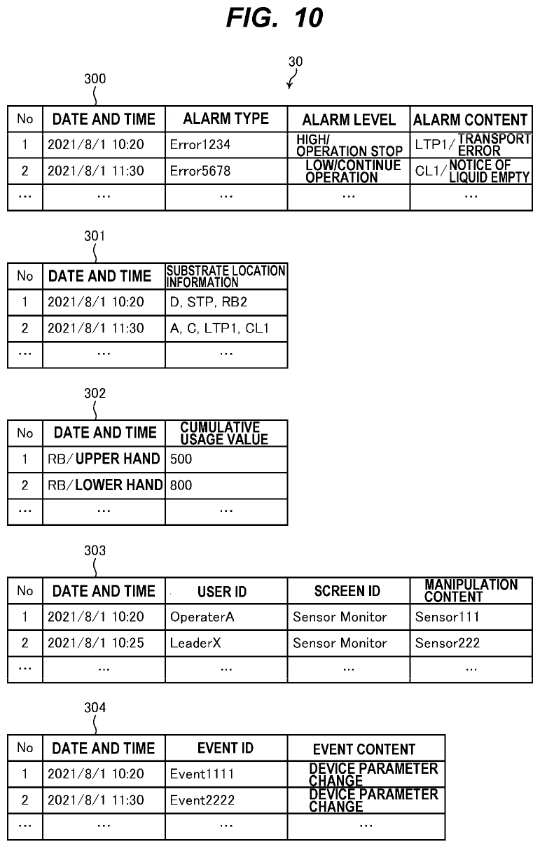

FIG. 10 is a data configuration diagram showing an example of history information 30 managed by the database device 3. The history information 30 includes tables in which the various reports R from the substrate processing device 2 are classified and registered. Specifically, the tables include an alarm history table 300 regarding alarm, a substrate-location history table 301 regarding the location state of wafers W, an operation history table 302 regarding operation state of each module, a manipulation history table 303 regarding manipulations of the user, and an event history table 304 regarding events.

For example, date and time, alarm type, alarm level, and alarm content are registered in each record of the alarm history table 300.

For example, date and time, and the substrate-location information are registered in each record of the substrate-location history table 301. The substrate-location information is information indicating the presence or absence of a wafer W at each position in the module group.

For example, a module ID and a cumulative usage value (cumulative usage time or cumulative usage count) are registered in each record of the operation history table 302. The operation history table 302 may register the date and time when each module was operated and the operation content (the change over time) as data that can be used to compile the cumulative usage value.

For example, date and time, user ID, screen ID, and manipulation content are registered in each record of the manipulation history table 303. The user ID is information that identifies the user who performed the manipulation or operation on the substrate processing device 2. The screen ID is information that identifies the display screen on which the user performed the manipulation. The manipulation content is information that specifies the details of the user's manipulation, and includes, for example, the user's manipulations for the display-object sensor identifying field 131, the display-object time range specifying field 132, and the display-object event identifying field 133 in the sensor monitor screen 13, and editing content of the device setting information 255 in the device-parameter editing screen.

For example, date and time, event ID, and event content are registered in each record of the event history table 304. The event ID is information that identifies an event that occurred in the substrate processing device 2. The event content is information that specifies the details of the event. For example, when the device setting information 255 is changed, the event content includes a value of the device parameter that has been changed.

By focusing on the dates and times of the alarm history table 300, the substrate-location history table 301, the manipulation history table 303, and the event history table 304, the location state of the wafers W when a certain alarm is generated, the contents of the user's manipulations performed before and after the alarm, and settings changes in the device setting information 255 are extracted.

### (Machine-Learning Device 4)

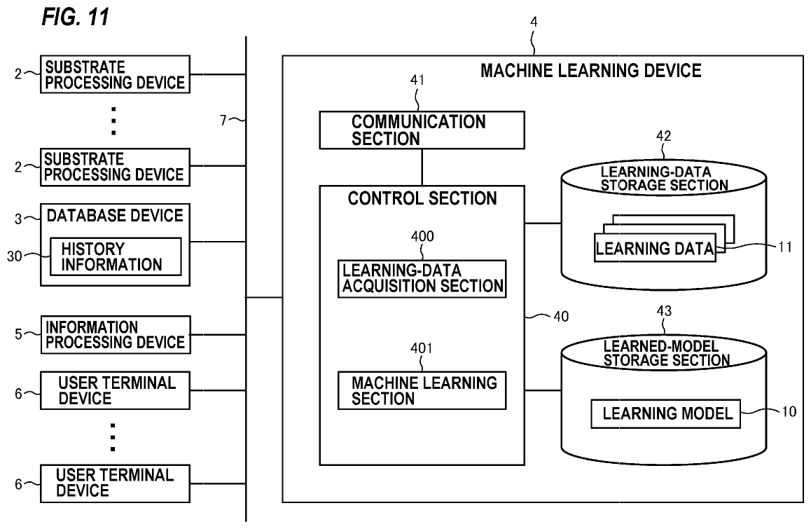

FIG. 11 is a block diagram showing an example of the machine-learning device 4. The machine-learning device 4 includes a control section 40, a communication section 41, a learning-data storage section 42, and a learned-model storage section 43.

The control section 40 functions as a learning-data acquisition section 400 and a machine-learning section 401. The communication section 41 is coupled to external devices (for example, the substrate processing device 2, the database device 3, the information processing device 5, the user terminal device 6, etc.) via the network 7. The communication section 41 serves as a communication interface for transmitting and receiving various data.

The learning-data acquisition section 400 is coupled to an external device via the communication section 41 and the network 7. The learning-data acquisition section 400 obtains the learning data 11 including the alarm generation information regarding an alarm generated in the substrate processing device 2 and the support information for dealing with the alarm generated.

The learning-data storage section 42 is a database that stores multiple sets of learning data 11 acquired by the learning-data acquisition section 400. The specific configuration of the database that constitutes the learning-data storage section 42 may be designed as appropriate.

The machine-learning section 401 performs the machine learning using the multiple sets of learning data 11 stored in the learning-data storage section 42. Specifically, the machine-learning section 401 inputs the multiple sets of learning data 11 to the learning model 10 and causes the learning model 10 to learn the correlation between the alarm generation information and the support information included in the learning data 11 to thereby create the learning model 10 as a learned model. In this embodiment, a neural network is employed as the learning model 10 that realizes the machine learning (supervised learning) performed by the machine-learning section 401.

The learned-model storage section 43 is a database that stores the learning model 10 as a learned model (i.e., adjusted weight parameter group) created by the machine-learning section 401. The learning model 10 as the learned model stored in the learned-model storage section 43 is provided to a real system (for example, the information processing device 5) via the network 7, a storage medium, or the like. Although the learning-data storage section 42 and the learned-model storage section 43 are shown as separate storage sections in FIG. 11, they may be configured as a single storage section.

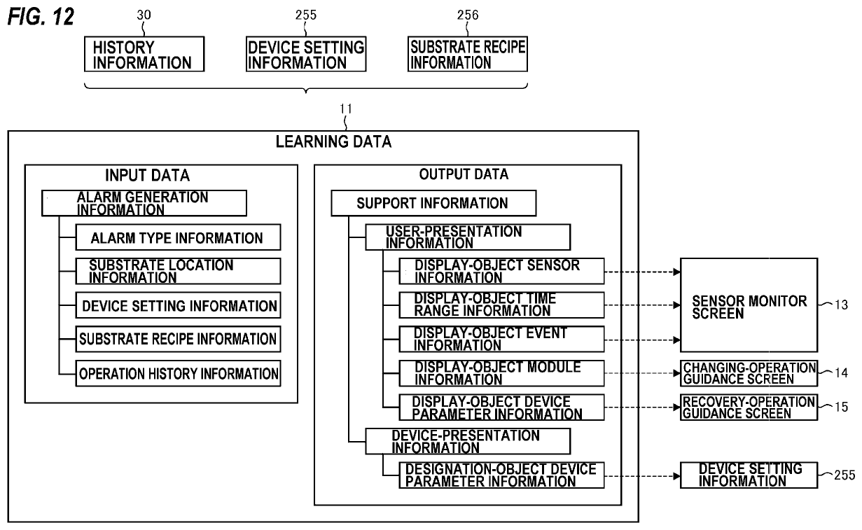

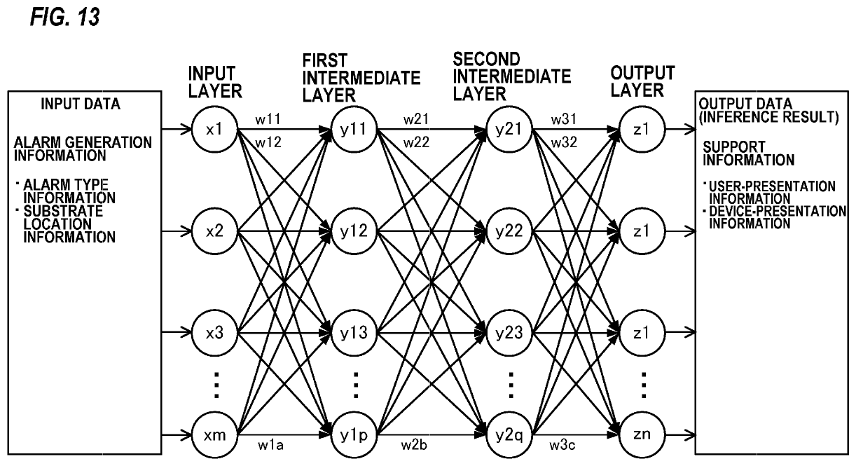

FIG. 12 is a data configuration diagram showing an example of the learning data 11. As discussed previously, the learning data 11 includes the alarm generation information as input data and the support information as output data. The learning data 11 is data used as teaching data (or training data), verification data, and test data in supervised learning. The support information is used as ground-truth label or correct label in supervised learning.

The alarm generation information includes at least alarm-type information indicating the type of alarm generated in the substrate processing device 2, and substrate-location information indicating the location state of the wafers W existing at respective positions of the module group when the alarm is generated. The alarm generation information may further include at least one of the device setting information 255 containing the device parameters that have been set in the modules, respectively, the substrate recipe information 256 indicating recipes for the wafers W that are present in the modules when the alarm is generated, and the operation history information indicating the operation histories of the modules. In this case, the device setting information 255 may include only a part of the device parameters, the substrate recipe information 256 may include only a part of the parameters, and the operation history information may include only a part of the operation histories.

The support information includes at least one of the user-presentation information regarding information to be provided to the user of the substrate processing device 2 and the device-presentation information regarding information to be provided to the substrate processing device 2.

The user-presentation information includes the display-object sensor information that identifies at least one sensor to be displayed on the sensor monitor screen 13. The user-presentation information may include the display-object time range information that specifies the time range when displaying the change over time on the sensor monitor screen 13, or may include the display-object event information that identifies at least one event to be displayed on the sensor monitor screen 13.

The user-presentation information may further include the display-object module information that identifies at least one module to be displayed on the recovery-operation guidance screen 14, and may further include the display-object device parameter information that identifies at least one device parameter to be displayed on the changing-operation guidance screen 15.

The device-presentation information includes the designation-object device parameter information that identifies at least one device parameter to be designated with respect to the changing-process designation data.

The learning-data acquisition section 400 is configured to refer to the history information 30 of the database device 3 and the device setting information 255 and the substrate recipe information 256 of the substrate processing device 2. When an alarm was generated in the past, the learning-data acquisition section 400 extracts the manipulations performed by a certain user (who has experience and knowledge to deal with the alarm) and the operating state of the substrate processing device 2 to thereby obtain the learning data 11.

For example, the alarm-type information, the substrate-location information, and the operation history information included in the alarm generation information can be obtained by the learning-data acquisition section 400 referring to the alarm history table 300, the substrate-location history table 301, and the operation history table 302. The device setting information 255 and the substrate recipe information 256 included in the alarm generation information can be obtained by the learning-data acquisition section 400 referring to the device setting information 255 and the substrate recipe information 256 of the substrate processing device 2 or can be obtained by the learning-data acquisition section 400 referring to events related to setting changes in the device setting information 255 and the substrate recipe information 256 in the event history table 304. The support information is obtained by the learning-data acquisition section 400 referring to the manipulation history table 303 based on the date and time when the alarm is generated, or obtained by the learning-data acquisition section 400 referring to events related to setting changes in the device setting information 255 and the substrate recipe information 256 in the event history table 304.

FIG. 13 is a schematic diagram showing an example of a neural network model that constitutes the learning model 10 used in the machine-learning device 4. The learning model 10 is configured as, for example, a neural network model shown in FIG. 13.

The neural network model includes m neurons (x1 to xm) in an input layer, p neurons (y11 to y1p) in a first intermediate layer, q neurons (v21 to y2q) in a second intermediate layer, and n neurons (z1 to zn) in an output layer.

Each neuron in the input layer is associated with the alarm generation information included in the learning data 11. Each neuron in the output layer is associated with the support information included in the learning data 11. Pre-processing may be performed on the input data before being input to the input layer, and post-processing may be performed on the output data after being output from the output layer.

The first intermediate layer and the second intermediate layer are also called hidden layers, and the neural network may have a plurality of hidden layers in addition to the first intermediate layer and the second intermediate layer. Only the first intermediate layer may be a hidden layer. There are synapses connecting neurons in each layer between the input layer and the first intermediate layer, between the first intermediate layer and the second intermediate layer, and between the second intermediate layer and the output layer. Each synapse is associated with a weight wi (i is a natural number).

### (Machine-Learning Method)

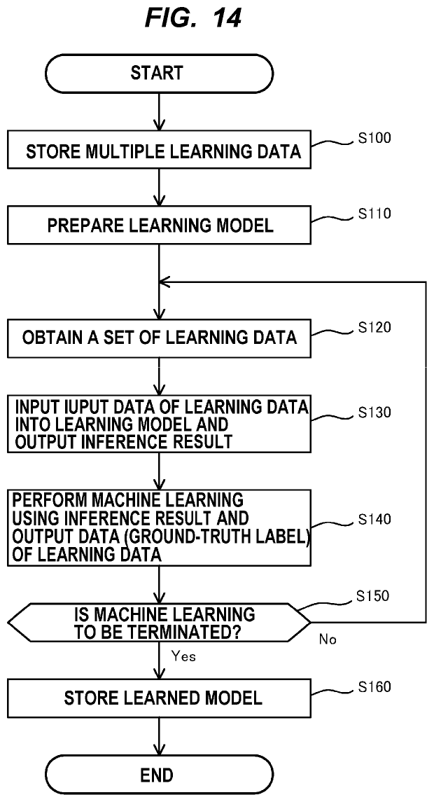

FIG. 14 is a flowchart illustrating an example of a machine-learning method performed by the machine-learning device 4.

First, in step S100, the learning-data acquisition section 400 obtains, from the history information 30, a desired number of learning data 11 as advance preparation for starting the machine learning, and stores the obtained learning data 11 in the learning-data storage section 42. The number of learning data 11 to be prepared may be set in consideration of the inference accuracy required for the learning model 10 finally obtained.

Next, in step S110, the machine-learning section 401 prepares the learning model 10 before learning for starting the machine learning. The learning model 10 prepared before learning in this embodiment is composed of the neural network model illustrated in FIG. 13, and the weight of each synapse is set to an initial value.

Next, in step S120, the machine-learning section 401 randomly obtains, for example, one set of learning data 11 from the multiple sets of learning data 11 stored in the learning-data storage section 42.

Next, in step S130, the machine-learning section 401 inputs the alarm generation information (the input data) included in the one set of learning data 11 to the input layer of the prepared learning model 10 before learning (or during learning). As a result, the support information (the output data) is output as the inference result from the output layer of the learning model 10. However, the output data is generated by the learning model 10 before learning (or during learning). Therefore, in the state before learning (or during learning), the output data as the inference result may indicate different information from the support information (ground-truth label) included in the learning data 11.

Next, in step S140, the machine-learning section 401 performs the machine learning by comparing the support information (ground-truth label) included in the one set of learning data 11 acquired in the step S120 with the support information (the output data) as the inference result output from the output layer in the step S130, and adjusting the weight wi of each synapse (backpropagation). In this way, the machine-learning section 401 causes the learning model 10 to learn the correlation between the alarm generation information and the support information.

Next, in step S150, the machine-learning section 401 determines whether or not a predetermined learning end condition is satisfied. For example, this determination is made based on an evaluation value of an error function based on the support information (ground-truth label) included in the learning data and the support information (the output data) output as the inference result, or based on the remaining number of unlearned learning data stored in the learning-data storage section 42.

In step S150, if the machine-learning section 401 has determined that the learning end condition is not satisfied and the machine learning is to be continued (No in step S150), the process returns to the step S120, and the steps S120 to S140 are performed on the learning model 10 multiple times using the unlearned learning data 11. On the other hand, in step S150, if the machine-learning section 401 has determined that the learning end condition is satisfied and the machine learning is to be terminated (Yes in step S150), the process proceeds to step S160.

Then, in step S160, the machine-learning section 401 stores, in the learned-model storage section 43, the learning model 10 as the learned model (adjusted weight parameter group) generated by adjusting the weight associated with each synapse. The sequence of machine-learning processes shown in FIG. 14 is completed. In the machine-learning method, the step S100 corresponds to a learning-data storing process, the steps S110 to S150 correspond to a machine-learning process, and the step S160 corresponds to a learned-model storing process.

As described above, the machine-learning device 4 and the machine-learning method according to the present embodiment can provide the learning model 10 that can generate (infer) support information for dealing with the alarm from the alarm generation information including at least the type of alarm generated in the substrate processing device 2 and the location state of the wafers W at the time of the generation of the alarm.

### (Information Processing Device 5)

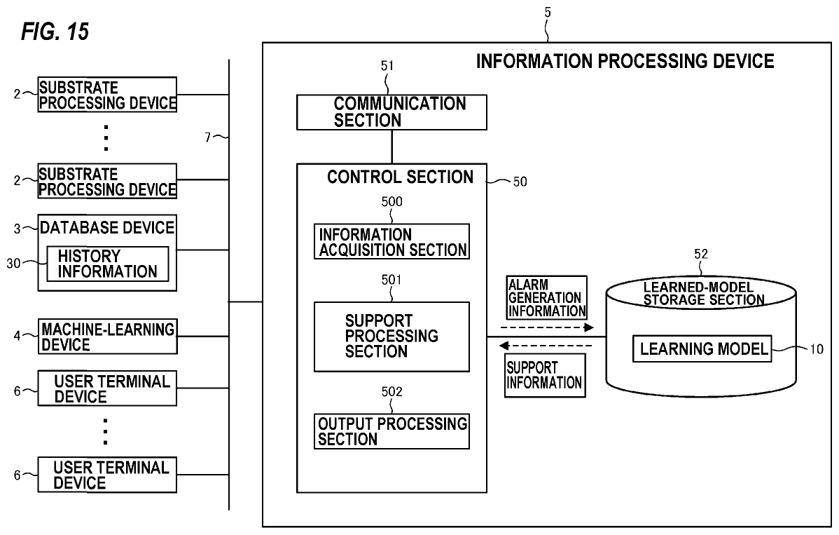

FIG. 15 is a block diagram showing an example of the information processing device 5. The information processing device 5 includes a control section 50, a communication section 51, and a learned-model storage section 52.

The control section 50 functions as an information acquisition section 500, a support processing section 501, and an output processing section 502. The communication section 51 is coupled to external devices (for example, the substrate processing device 2, the database device 3, the machine-learning device 4, the user terminal device 6, etc.) via the network 7, and serves as a communication interface for transmitting and receiving various data.

The information acquisition section 500 is coupled to an external device via the communication section 51 and the network 7 and acquires the alarm generation information, which includes at least the alarm-type information indicating the type of alarm generated in the substrate processing device 2 and the substrate-location information indicating the location state of the wafers W at the time of generation of the alarm. For example, the information acquisition section 500 acquires the alarm generation information by receiving from the substrate processing device 2 a report R regarding generation of an alarm and a report R regarding the location state of the wafers W at the time of generation of the alarm. Further, the information acquisition section 500 may acquire the operation history information at the time of generation of the alarm as other information to be added to the alarm generation information by referring to the history information 30 of the database device 3, or may acquire the device setting information 255 and the substrate recipe information 256 at the time of generation of the alarm by referring to the device setting information 255 and the substrate recipe information 256 of the substrate processing device 2.

The support processing section 501 generates the support information corresponding to the alarm by inputting the alarm generation information acquired by the information acquisition section 500 into the learning model 10 in response to the generation of the alarm.

The learned-model storage section 52 is a database that stores the learning model 10 as the learned model to be used in the support processing section 501. The number of learning models 10 stored in the learned-model storage section 52 is not limited to one. For example, multiple learning models 10 may be stored in the learned-model storage section 52 for different conditions, such as for a machine-learning method, a type of data included in the alarm generation information, a type of data included in the support information, etc. These multiple learning models 10 may be selectively used. The learned-model storage section 52 may be a memory section of an external computer (for example, a server type computer or a cloud type computer). In that case, the support processing section 501 accesses the external computer and generates the above-mentioned support information.

The output processing section 502 performs output processing to output the support information generated by the support processing section 501. For example, when the support information is the user-presentation information, the output processing section 502 transmits a command C regarding the user-presentation information to the substrate processing device 2. When the support information is the device-presentation information, the output processing section 502 transmits a command C regarding the device-presentation information to the substrate processing device 2. The output processing section 502 may transmit the support information to the user terminal device 6, and the user terminal device 6 may display the display screen based on the support information. The output processing section 502 may transmit the support information to the database device 3, and the support information may be stored in the database device 3 so that the substrate processing device 2 and the user terminal device 6 can refer to the support information.

### (Information Processing Method)

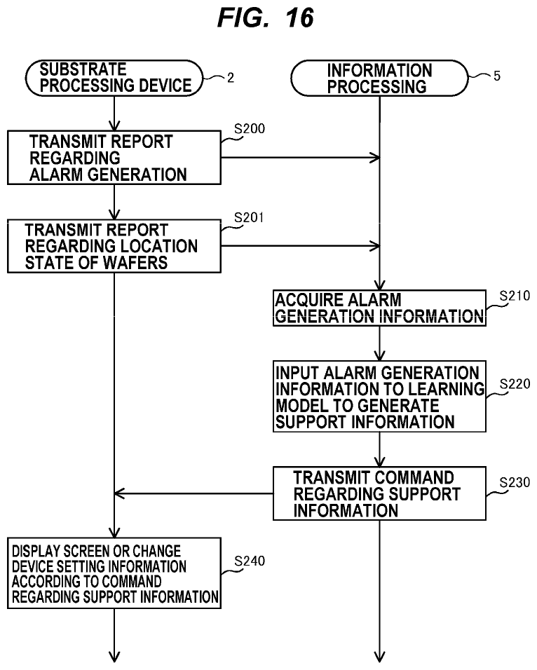

FIG. 16 is a flowchart illustrating an example of an information processing method performed by the information processing device 5. In this embodiment, operations will be described in a case where the substrate processing device 2 generates an alarm according to a predetermined alarm-generating condition during automatic operation in which wafers W are sequentially loaded from the wafer cassettes and the wafers W are polished.

First, in step S200, when the substrate processing device 2 detects generation of an alarm, the substrate processing device 2 transmits a report R regarding the generation of the alarm. Then, in step S201, the substrate processing device 2 transmits a report R regarding the location state of the wafers W detected by the sensor group at the time when the alarm is generated. The two reports R in the steps S200 and S201 may be transmitted as one report R.

Next, in step S210, the information acquisition section 500 of the information processing device 5 acquires the alarm generation information by receiving the reports R transmitted in the steps S200 and S201. The reports R transmitted in the steps S200 and S201 are also received by the database device 3 and registered in the history information 30.

Next, in step S220, the support processing section 501 generates the support information corresponding to the alarm by inputting the alarm generation information acquired in the step S210 to the learning model 10.

Next, in step S230, the output processing section 502 transmits a command C regarding the support information to the substrate processing device 2 as an output process for outputting the support information generated in the step S220. The command C may be transmitted to the database device 3 or the user terminal device 6 in addition to or instead of the substrate processing device 2 that has detected the generation of the alarm. In one example, the learning model 10 may output, as the support information, the user-presentation information including the display-object sensor information, the display-object time range information, and the display-object event information. In that case, the output processing section 502 transmits a command C regarding the user-presentation information including the above information.

Next, in step S240, upon receiving the command C transmitted in the step S230, the substrate processing device 2 displays the display screen based on the user-presentation information if the command C is related to the user-presentation information. If the command C is related to the device-presentation information, the substrate processing device 2 changes the device setting information 255 based on the designation-object device parameter information included in the device-presentation information. Then, the series of information processing method shown in FIG. 16 is terminated. In the information processing method, the step S210 corresponds to an information acquisition step, the step S220 corresponds to a support processing step, and the step S230 corresponds to an output processing step.

The step S240 will be described with reference to the above learning model 10 as an example. The substrate processing device 2 displays the sensor monitor screen 13 corresponding to the user-presentation information. On the sensor monitor screen 13, the sensor identified in the display-object sensor information is identified in the display-object sensor identifying field 131, the time range specified in the display-object time range information is specified in the display-object time range specifying field 132, and the event identified in the display-object event information is identified in the display-object event identifying field 133. The user (for example, an operator) of the substrate processing device 2 that has detected the generation of the alarm can check the state or condition of the substrate processing device 2 while visually checking the sensor monitor screen 13 displayed on the substrate processing device 2, so that the user can analyze the cause of the alarm and can recover the substrate processing device 2 from the alarm state to the normal state.

As described above, according to the information processing device 5 and the information processing method according to the present embodiment, the alarm generation information is input to the learning model 10 in response to the generation of the alarm, so that the support information corresponding to the alarm is generated. Therefore, the user can address the alarm quickly and appropriately without relying on the user's experience or knowledge.

### OTHER EMBODIMENTS

The present invention is not limited to the above-described embodiments, and various modifications can be made and used without deviating from the scope of the present invention. All of them are included in the technical concept of the present invention.

In the above embodiments, the database device 3, the machine-learning device 4, and the information processing device 5 are described as being configured as separate devices, but these three devices may be configured as a single device. In one embodiment, any two of these three devices may be configured as a single device. Further, at least one of the machine-learning device 4 and the information processing device 5 may be incorporated into the control unit 25 of the substrate processing device 2.

In the embodiments described above, the neural network is employed as the learning model 10 that implements the machine learning performed by the machine-learning section 401, while other machine-learning model may be employed. Examples of the other machine-learning model include tree type (e.g., decision tree, regression tree), ensemble learning (e.g., bagging, boosting), neural network type including deep learning (e.g., recurrent neural network, convolutional neural network, LSTM), clustering type (e.g., hierarchical clustering, non-hierarchical clustering, k-nearest neighbor algorithm, k-means clustering), multivariate analysis (e.g., principal component analysis, factor analysis, logistic regression), and support vector machine.

### (Machine Learning Program and Information Processing Program)

The present invention can be provided in a form of a program (machine learning program) that causes the computer 900 to function as each section of the machine-learning device 4, and in a form of a program (machine learning program) that causes the computer 900 to execute each process of the machine-learning method. Further, the present invention can be provided in a form of a program (information processing program) that causes the computer 900 to function as each section included in the information processing device 5, and in a form of a program (information processing program) that causes the computer 900 to execute each process included in the information processing method according to the above embodiments.

### (Inference Apparatus, Inference Method, and Inference Program)

The present invention can be provided in a form of not only the information processing device 5 (information processing method or information processing program) according to the above embodiments, but also in a form of an inference apparatus (inference method or inference program) used for inferring the support information. In that case, the inference apparatus (inference method or inference program) may include a memory and a processor. The processor may execute a series of processes. The series of processes includes information acquisition processing (information acquisition process) that acquires the alarm generation information including at least the alarm-type information indicating the type of alarm generated in the substrate processing device 2 and the substrate-location information indicating the location state of the substrates present in the modules when the alarm is generated, and inference processing (inference process) that infers the support information for dealing with the generation of the alarm when the alarm generation information is acquired in the information acquisition processing in response to the generation of the alarm.

The form of the inference apparatus (inference method or inference program) can be applied to various devices more easily than when the information processing device is implemented. It is readily understood by a person skilled in the art that the inference method performed by the support processing section may be applied with use of the learning model 10 as the learned model generated by the machine-learning device 4 and the machine-learning method according to the above embodiments when the inference apparatus (inference method or inference program) infers the support information.

### INDUSTRIAL APPLICABILITY

The present invention is applicable to information processing apparatus, an inference apparatus, a machine-learning apparatus, an information processing method, an inference method, and a machine-learning method.

### REFERENCE SIGNS LIST

1 . . . substrate processing system, 2 . . . substrate processing device, 3 . . . database device, 4 . . . machine-learning device, 5 . . . information processing device, 6 . . . user terminal device, 7 . . . network, 10 . . . learning model, 11 . . . learning data, 12 . . . substrate-location-state display screen, 13 . . . sensor monitor screen, 14 . . . recovery-operation guidance screen, 15 . . . changing-operation guidance screen, 20 . . . housing, 21 . . . load-unload unit, 22 . . . polishing unit, 23 . . . cleaning unit, 24 . . . film-thickness measuring unit, 25 . . . control unit, 30 . . . history information, 40 . . . control section, 41 . . . communication section, 42 . . . learning-data storage section, 43 . . . learned-model storage section, 50 . . . control section, 51 . . . communication section, 52 . . . learned-model storage section, 120 . . . wafer present mark, 121 . . . wafer absent mark, 130 . . . graph area, 131 . . . display-object sensor identifying field, 132 . . . display-object time range specifying field, 133 . . . display-object event identifying field, 140 . . . alarm display field, 141 . . . recovery-operation guidance field, 150 . . . alarm display field, 151 . . . changing-operation guidance field, 200A, 200B . . . partition wall, 210A-210D . . . front-load section, 211 . . . transfer robot, 212 . . . moving mechanism, 220A-220D . . . polishing section, 221A, 221B . . . linear transporter, 222 . . . swing transporter, 223 . . . lifter, 224 . . . temporary station, 230A, 230B . . . cleaning chamber, 231 . . . drying chamber, 232A, 232B . . . transporting chambers, 233A, 233B . . . transfer robot, 250 . . . control section, 251 . . . communication section, 252 . . . input section, 253 . . . output section, 254 . . . storage section, 255 . . . device setting information, 256 . . . substrate recipe information, 300 . . . alarm history table, 301 . . . substrate-location history table, 302 . . . operation history table, 303 . . . manipulation history table, 304 . . . event history table, 400 . . . learning-data acquisition section, 401 . . . machine-learning section, 500 . . . information acquisition section, 501 . . . support processing section, 502 . . . output processing section, 2200 . . . polishing pad, 2201 . . . polishing table, 2202 . . . top ring, 2203 . . . polishing-liquid supply nozzle, 2204 . . . dresser, 2205 . . . atomizer

1. An information processing apparatus comprising:
an information acquisition section configured to acquire alarm generation information including at least alarm-type information and substrate-location information, the alarm-type information indicating a type of alarm that is generated in a substrate processing device including modules and is configured to perform polishing process on substrates, the substrate-location information indicating a location state of the substrates in the modules when the alarm is generated; and
a support processing section configured to generate support information corresponding to the alarm by inputting the alarm generation information acquired by the information acquisition section in response to the generation of the alarm to a learning model that has learned by machine learning a correlation between the alarm generation information and the support information for dealing with generation of the alarm.

2. The information processing apparatus according to claim 1, wherein the alarm generation information further includes at least one of:
substrate recipe information indicating recipes for the substrates that exist in the modules when the alarm is generated;
device setting information including device parameters set for the modules, respectively; and
operation history information indicating operation histories of the modules.

3. The information processing apparatus according to claim 1, wherein the support information includes at least one of:
user-presentation information regarding information provided to a user of the substrate processing device; and
device-presentation information regarding information provided to the substrate processing device.

4. The information processing apparatus according to claim 3, wherein the user-presentation information includes display-object sensor information that identifies at least one sensor to be displayed on a sensor monitor screen capable of displaying a change over time in a detection value of the at least one sensor which is among sensors arranged in the modules.

5. The information processing apparatus according to claim 4, wherein the user-presentation information includes display-object time range information that specifies a time range when displaying the change over time on the sensor monitor screen.

6. The information processing apparatus according to claim 4, wherein the user-presentation information includes display-object event information that identifies at least one event to be displayed on the sensor monitor screen capable of displaying a detection time of the at least one event which is among events detected in the substrate processing device.

7. The information processing apparatus according to claim 3, wherein the user-presentation information includes display-object module information that identifies at least one module to be displayed on a recovery-operation guidance screen capable of displaying a guidance of a recovery operation for the at least one module which is among the modules.

8. The information processing apparatus according to claim 3, wherein the user-presentation information includes display-object device parameter information that identifies at least one device parameter to be displayed on a changing-operation guidance screen capable of displaying a guidance for changing the at least one device parameter which is one of device parameters set in the modules.

9. The information processing apparatus according to claim 3, wherein the device-presentation information includes designation-object device parameter information that identifies at least one device parameter to be identified with respect to changing-process designation data that can designate a changing process for the at least one device parameter which is among device parameters set in the modules.

10. An inference apparatus comprising:
a memory; and
a processor configured to perform;
an information acquisition processing of acquiring alarm generation information including at least alarm-type information and substrate-location information, the alarm-type information indicating a type of alarm that is generated in a substrate processing device including modules and is configured to perform polishing process on substrates, the substrate-location information indicating a location state of the substrates in the modules when the alarm is generated; and
an inference processing of inferring support information for dealing with generation of the alarm when the alarm generation information is acquired in response to generation of the alarm in the information acquisition processing.

11. A machine-learning apparatus comprising:
a learning-data storage section storing multiple sets of learning data including alarm generation information and support information, the alarm generation information including at least alarm-type information and substrate-location information, the alarm-type information indicating a type of alarm that is generated in a substrate processing device including modules and is configured to perform polishing process on substrates, the substrate-location information indicating a location state of the substrates in the modules when the alarm is generated, the support information indicating information for dealing with generation of the alarm;
a machine-learning section configured to cause a learning model to learn a correlation between the alarm generation information and the support information by inputting the multiple sets of learning data to the learning model; and
a learned-model storage section configured to store the learning model that has learned the correlation by the machine-learning section.

12. (canceled)

13. (canceled)

14. (canceled)
